(19) United States
(12) Patent Application Publication
(10) Pub. No.: US 2023/0415988 A1
(43) Pub. Date: Dec. 28, 2023

(54) STORAGE SHELF AND CEILING CONVEYANCE CAR SYSTEM

(71) Applicant: Murata Machinery, Ltd., Kyoto-shi, Kyoto (JP)

(72) Inventors: Tatsuo Tsubaki, Ise-shi, Mie (JP); Yoshiya Wada, Ise-shi, Mie (JP)

(21) Appl. No.: 18/038,237

(22) PCT Filed: Oct. 5, 2021
(86) PCT No.: PCT/JP2021/036805

§ 371 Date: May 23, 2023

(30) Foreign Application Priority Data
Nov. 26, 2020 (JP) 2020-196124

(51) Int. Cl. B65G 1/04; B65G 47/61; B65G 47/82

(52) U.S. Cl. CPC B65G 1/0457; B65G 47/61; B65G 47/82; B65G 2203/0283; B65G 2203/047

(57) ABSTRACT

A storage shelf installed on a side of a track, to and from which an article is delivered by a lateral transfer mechanism of an overhead transport vehicle traveling in the track in a traveling direction, includes a stopper configured to come into contact with a part of the lateral transfer mechanism having moved by a predetermined amount or more in a lateral direction perpendicular to the traveling direction.

### TECHNICAL FIELD

This disclosure relates to a storage shelf and an overhead transport vehicle system.

### BACKGROUND

Conventionally, as described in Japanese Unexamined Patent Publication No. 2009-120299, in an overhead vehicle system in which an overhead vehicle travels along a pair of traveling rails suspended from a ceiling, a configuration in which a side buffer is provided between traveling rails is known. The side buffer has a post attached to a beam, a girder fixed to a bottom of the post, and a pedestal attached onto the girder, and the like. On the pedestal, an article received from an overhead vehicle is placed.

In the overhead vehicle system, when an article is delivered from or to the side buffer (storage shelf), the overhead vehicle laterally moves a turning unit, a lifting drive, and a lifting platform by a lateral drive. Furthermore, by the lifting drive, the lifting platform is lowered together with a chuck (gripping part) gripping the article, and the article is placed on the side buffer. Alternatively, the overhead vehicle lowers the chuck together with the lifting platform, and grips the article placed on the side buffer with the chuck to raise the article.

When the lateral drive (lateral transfer unit) moves the lifting platform and the like in a lateral direction, the lifting platform and the like are usually positioned and controlled to stop at a predetermined position. However, if an original positioning control is no longer possible due to some abnormalities in the overhead vehicle or other reasons, the lateral drive may possibly move the lifting platform and the like laterally to the mechanical operating limit (stroke limit). When the parts including: the lateral transfer unit; and the lifting platform and the like, are collectively regarded as a lateral transfer mechanism, the lateral transfer mechanism can move to a mechanically operable limit. When the lateral transfer mechanism has moved to the limit, it will protrude to a far side in a transfer direction. For example, in a system in which a pair of traveling rails (tracks) as described in JP '299 are provided, sufficient track spacing is set so that even if the aforementioned situation occurs, the lateral transfer mechanism protruded laterally will not come into contact with an overhead vehicle traveling in an opposite lane.

It could therefore be helpful to provide a storage shelf and an overhead transport vehicle system capable of preventing a lateral transfer mechanism of an overhead transport vehicle from protruding to the far side in a transfer direction.

### SUMMARY

We thus provide a storage shelf that is installed on a side of a track, and to and from which an article is delivered by a lateral transfer mechanism of an overhead transport vehicle traveling in the track in a traveling direction, the storage shelf including a stopper with which a part of the lateral transfer mechanism comes into contact, the lateral transfer mechanism having moved by a predetermined amount or more in a lateral direction perpendicular to the traveling direction.

With this storage shelf, when the lateral transfer mechanism of the overhead transport vehicle moves by a predetermined amount or more in the transfer direction, the stopper comes into contact with a part of the lateral transfer mechanism. This “predetermined amount” is set, for example, to be slightly larger than a penetration amount (advancement amount) in a transfer direction that is controlled for positioning in a normal lateral transfer operation. In the normal lateral transfer operation, the lateral transfer mechanism never comes into contact with the stopper. However, even if the lateral transfer mechanism moves by a predetermined amount or more in the transfer direction due to some abnormalities in the overhead transport vehicle, the stopper can prevent the mechanism from protruding to the far side in the transfer direction. As a result, it is possible to dispose other devices or apparatuses that can be disposed on an opposite side to the track, or different tracks (overhead transport vehicles) or the like closer to each other, thereby increasing the degree of layout flexibility. In addition, the storage shelves can also be installed in close proximity to a wall of a factory or the like.

The stopper may have an elastic portion attached to a side surface facing a part of the lateral transfer mechanism. Even when the lateral transfer mechanism comes into contact with the stopper, there may be situations in which the movement (penetration) of the lateral transfer mechanism does not stop immediately (when the lateral transfer mechanism coasts). Even if the lateral transfer mechanism coasts, the elastic portion of the stopper absorbs impact while being deformed. As a result, it is possible to prevent damage to the stopper and the lateral transfer mechanism at the time of contact.

The stopper may include an elastic body. Even when the lateral transfer mechanism comes into contact with the stopper, there may be a situation in which the movement (penetration) of the lateral transfer mechanism does not stop immediately (when the lateral transfer mechanism coasts). Even if the lateral transfer mechanism coasts, the stopper including the elastic body absorbs the impact while being deformed. As a result, it is possible to prevent damage to the stopper and the lateral transfer mechanism at the time of contact.

We also provide an overhead transport vehicle system including a track, an overhead transport vehicle traveling along the track, and a storage shelf of any of the above-described storage shelves may be provided. With this overhead transport vehicle system, even if the lateral transfer mechanism moves by a predetermined amount or more in the transfer direction due to some abnormalities in the overhead transport vehicle or other reasons, the stopper can prevent the lateral transfer mechanism from protruding to the far side in the transfer direction. As a result, it is possible to dispose other devices or apparatuses that can be disposed on an opposite side to the track, or the tracks or the like closer to each other, thereby increasing the degree of layout flexibility.

The overhead transport vehicle system may further include another track parallel to the track, and the storage shelf may be installed between the track and the other track. In this example, the first track (the above-described track) and the second track are laid on both sides of the storage shelf. Even if the lateral transfer mechanism of an overhead transport vehicle traveling on the first track moves by a predetermined amount or more in the transfer direction, the protrusion of the lateral transfer mechanism to the far side can be prevented. This can prevent the lateral transfer mechanism from coming into contact with an overhead transport vehicle traveling on the second track. Conventional storage shelves without stoppers need to be provided with sufficient track spacing to prevent such contact. However, in the storage shelf including a stopper, a distance between centers of the first track and the second track can be smaller than the track spacing that has been conventionally required.

In the overhead transport vehicle system, a part of the lateral transfer mechanism of the overhead transport vehicle may be provided with a contact sensor configured to detect contact with the stopper. In this example, the contact sensor can detect contact of the lateral transfer mechanism with the stopper. Controls such as stopping the lateral transfer mechanism, stopping the overhead transport vehicle, or generating an alarm to inform an operator are enabled.

Thus, even if the lateral transfer mechanism of the overhead transport vehicle moves by a predetermined amount or more in the transfer direction, the stopper can prevent the mechanism from protruding to the far side in the transfer direction.

### BRIEF DESCRIPTION OF THE DRAWINGS

FIG. 1 is a perspective view illustrating a storage shelf and tracks on both sides of the storage shelf in an overhead transport vehicle system according to one example.

FIG. 2 is a schematic side view illustrating the overhead transport vehicle system in FIG. 1.

FIG. 3 is a perspective view illustrating the storage shelf in FIG. 1.

FIG. 4(a) is a plan cross-sectional view illustrating a lateral transfer mechanism positioned in a transfer position, and FIG. 4(b) is a plan cross-sectional view illustrating the lateral transfer mechanism passing the transfer position to come into contact with the stopper.

FIG. 5(a) is a plan cross-sectional view illustrating the lateral transfer mechanism stopped by a stopper, following FIG. 4(b), and FIG. 5(b) is a plan cross-sectional view illustrating the lateral transfer mechanism operating to a stroke limit in a conventional storage shelf without a stopper.

FIG. 6 is a schematic side view illustrating a state in which the lateral transfer mechanism begins to come into contact with the stopper.

FIG. 7 is a schematic plan view of FIG. 6.

FIG. 8 is a schematic side view illustrating an overhead transport vehicle system to which the conventional storage shelf without a stopper is applied.

### REFERENCE SIGNS LIST

1 overhead transport vehicle system
4 track
4A first track
4B second track
6 overhead transport vehicle
7 lateral transfer mechanism
8 loading portion
9 shelf post
10 article
11 lateral move unit
11a corner portion
30 lifting platform (lifting unit)
31 gripping part
40 storage shelf
50 stopper
51 base unit
52 elastic portion
54 contact piece
56 spring
58 contact sensor
P1 loading position
P2 transfer position

### DETAILED DESCRIPTION

An example of our storage shelves and systems will now be described in detail with reference to the drawings.

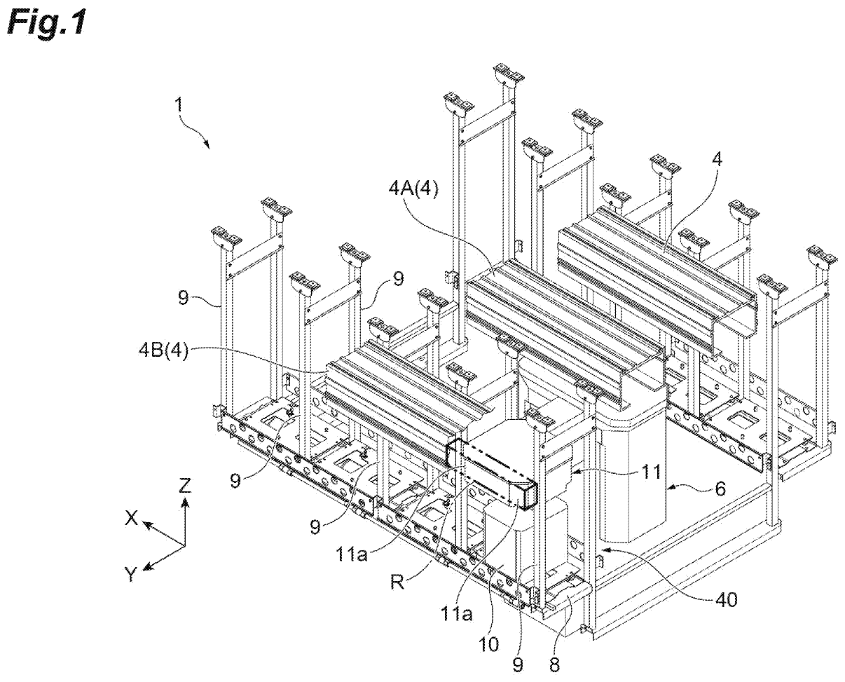

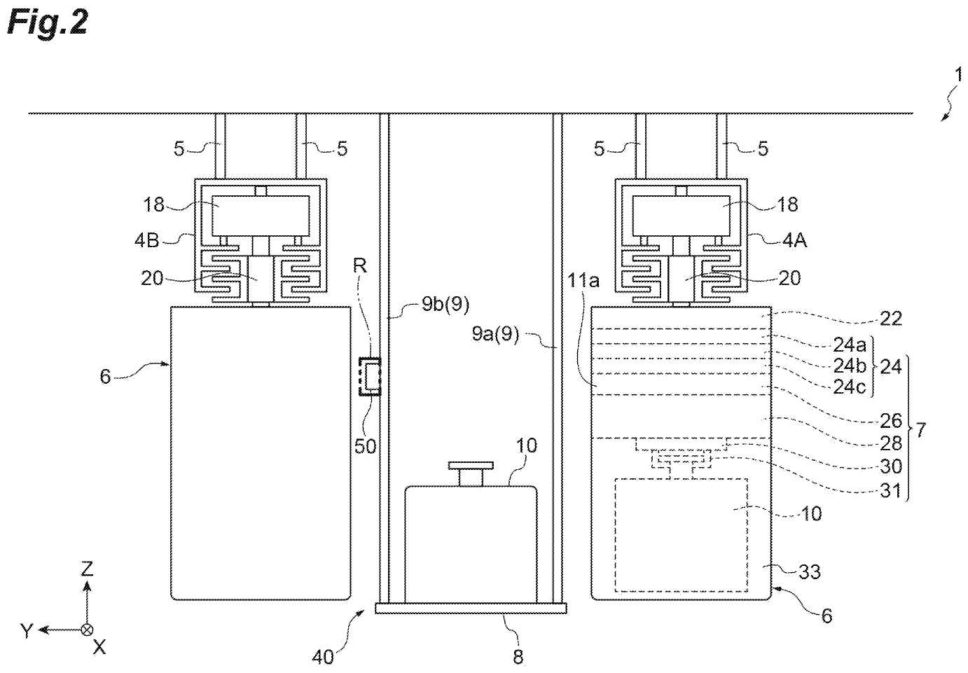

As illustrated in FIGS. 1 and 2, an overhead transport vehicle system 1 is a system configured to convey an article 10 using an overhead transport vehicle 6 capable of moving along a track. The article 10 includes, for example, a container for storing a plurality of semiconductor wafers, a container for storing a glass substrate, a reticle pod, general components, and the like. For example, in a factory or the like, the overhead transport vehicle system 1 is described as an example in which the overhead transport vehicle 6 (“transport vehicle 6” travels along a track 4 laid on a ceiling or the like of the factory. In the overhead transport vehicle system 1, a pair of tracks 4A, 4B parallel to each other are laid. Between the pair of tracks 4A and 4B, a storage shelf 40 including a loading portion 8 is installed for storing the article 10. The article 10 transferred from the transport vehicle 6 is placed on the loading portion 8. One storage shelf 40 may have a plurality of loading portions 8 or may have only one loading portion 8. The storage shelf 40 receives, supports, and stores the article 10 transferred from the transport vehicle 6. The overhead transport vehicle system 1 includes tracks 4A, 4B, a plurality of the transport vehicles 6, and a plurality of the storage shelves 40.

A first track 4A and a second track 4B are laid, for example, near the ceiling that is a space overhead of an operator. The first track 4A and the second track 4B are suspended from the ceiling, for example, and are installed at approximately the same height. The heights of the first track 4A and the second track 4B may be different as long as it is possible to transfer the article 10 from each of the transport vehicles 6 to the storage shelf 40. The first track 4A and the second track 4B are predetermined traveling paths allowing the transport vehicles 6 to travel thereon. Each of the first track 4A and the second track 4B is suspended and supported, for example, by track posts 5, 5. The storage shelves 40 are suspended and supported by a plurality of shelf posts 9.

The transport vehicle 6 is a ceiling traveling type unmanned vehicle. The transport vehicle 6 travels along the track 4 to convey the article 10. In the overhead transport vehicle system 1, each of the first track 4A and the second track 4B is a one-way track 4. For example, the transport vehicle 6 traveling on the first track 4A travels in one direction in the X direction (from the front of paper in FIG. 2 toward the back thereof). The transport vehicle 6 traveling on the second track 4B travels in the other direction in the X direction (from the back of the paper in FIG. 2 toward the front thereof). In other words, the transport vehicle 6 traveling in an opposite lane travels in an opposite direction along the X direction. The transport vehicle 6 is configured such that the article 10 is able to be transferred to the loading portion 8 of the storage shelf 40. For example, the transport vehicle 6 traveling on the first track 4A transfers the article 10 along the Y direction (lateral direction in a horizontal plane). The Y direction, which is a traveling direction of the article 10, is orthogonal to the X direction, which is the traveling direction of the transport vehicle 6, for example, in the horizontal plane. The number of the transport vehicles 6 included in the overhead transport vehicle system 1 is not limited to a particular number, and is two or more.

As illustrated in FIG. 2, the transport vehicle 6 has a traveling portion 18 configured to allow the transport vehicle 6 to travel along the track 4 and a power receiving communication unit 20 configured to receive power from the track 4 side, for example, by a contactless power feed. The transport vehicle 6 communicates with a controller, which is not illustrated, using a communication line (feeder line) or the like of the track 4. Note that the transport vehicle 6 may communicate with the controller via a feeder line provided along the track 4. The transport vehicle 6 includes a body frame 22, a lateral transfer unit 24, a θ drive 26, a lifting drive unit 28, a lifting platform (lifting unit) 30, and a body cover 33.

The lateral transfer unit 24 moves the θ drive 26, the lifting drive unit 28, and the lifting platform 30 all together in the Y direction. The lateral transfer unit 24 includes, for example, an upper member 24a attached to the body frame 22, a middle member 24b capable of advancing or retracting slidably in the Y direction along the upper member 24a, and a lower member 24c capable of advancing or retracting slidably in the Y direction along the middle member 24b. The θ drive 26 is attached on a lower side of the lower member 24c. The lateral transfer unit 24 has a drive motor, a belt, a gear, a pulley, and the like, to move the θ drive 26, the lifting drive unit 28, and the lifting platform 30 in the Y direction. The configuration of the lateral transfer unit 24 is not limited to the above, and other known configurations that enable lateral transfer of the article 10 may be employed.

The θ drive 26 holds the lifting drive unit 28 and the lifting platform 30, to rotate the lifting drive unit 28 within a predetermined angle range in a horizontal plane. The lifting drive unit 28 winds or pays out suspending members such as wires, ropes, and belts, thereby lifting or lowering the lifting platform 30. The lifting platform 30 is provided with a gripping part 31 (also called a chuck). The gripping part 31 is capable of gripping or releasing the article 10. The lifting platform 30 grips the article 10 and raises or lowers the articles 10. A pair of front and the rear covers 33 are provided on the front and the rear of the transport vehicle 6 in the traveling direction. The body cover 33 extends and retracts a claw or the like, which is not illustrated, with respect to the article 10 to prevent the article 10 from falling during conveyance.

The article 10 is temporarily placed on the loading portion 8 where the article 10 is delivered from or to the transport vehicles 6. On the loading portion 8, the article 10 is temporarily placed when, for example, the article 10 that is being conveyed by the transport vehicle 6 cannot be transferred to a delivery port as a destination (not illustrated) for some reasons such as that the delivery port has another article 10 placed thereon. The delivery port is a loading portion for performing delivery of the article 10 to and from a semiconductor processing device (not illustrated) including a cleaning apparatus, a deposition apparatus, a lithography apparatus, an etching apparatus, a thermal treatment apparatus, and a planarization apparatus.

As illustrated in FIG. 2, the storage shelf 40 is disposed along the track 4 and is provided at a position where the article 10 can be delivered from or to the transport vehicle 6. The storage shelf 40 is disposed on the side of the first track 4A. The storage shelf 40 is disposed on the side of the second track 4B. The transport vehicle 6 transfers the lifting drive unit 28 or the like by the lateral transfer unit 24 and slightly raises and lowers the lifting platform 30, to perform delivery of the article 10 from or to the loading portion 8 of the storage shelf 40.

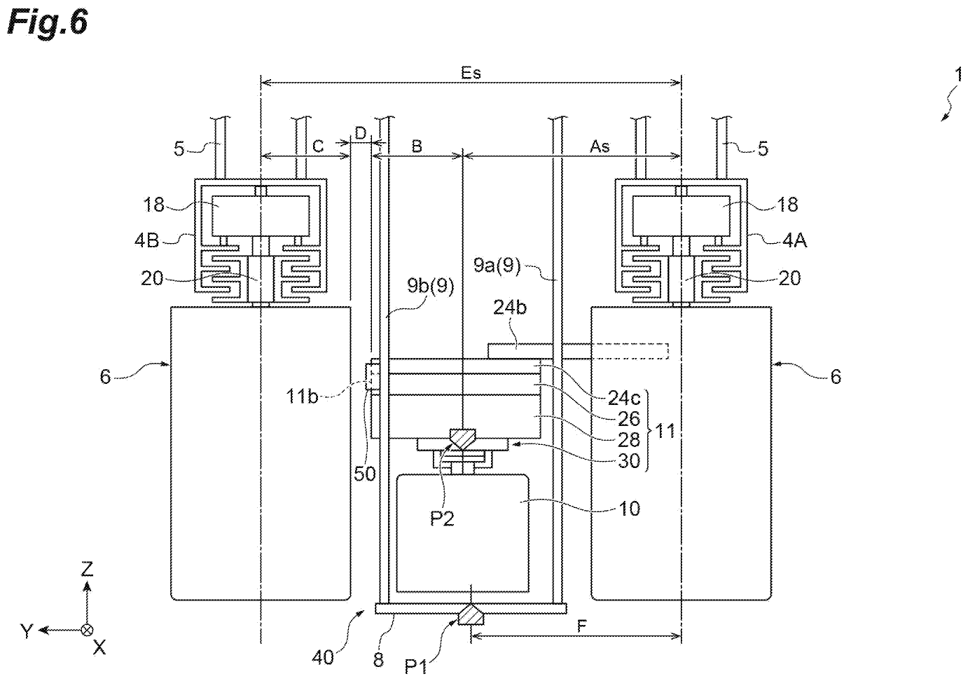

The overhead transport vehicle system 1 of this example has a structure limiting an excessive advancement in the Y direction of a lateral move unit 11 configured to advance toward the storage shelf 40. The transport vehicle 6 includes a lateral transfer mechanism 7 having the above-described lateral transfer unit 24, the θ drive 26, the lifting drive unit 28, and the lifting platform 30 including the gripping part 31. The transport vehicle 6 allows the lateral transfer mechanism 7 to transfer the article 10 to and from the loading portion 8 of the storage shelf 40. The transport vehicle 6 includes, as a part configured to advance in the Y direction when the article 10 is transferred, the lower member 24c of the lateral transfer unit 24, the θ drive 26, the lifting drive unit 28, and the lateral move unit 11 including the lifting platform 30. The lateral move unit 11 has a generally rectangular (parallelepiped) shape. The lateral move unit 11 is a part of the lateral transfer mechanism 7 and is a part configured to move to right above a loading position P1 of the article 10 on the loading portion 8 (see FIG. 6). In FIG. 6, the loading position P1 is indicated as a center position in the Y direction of the article 10 placed on the loading portion 8.

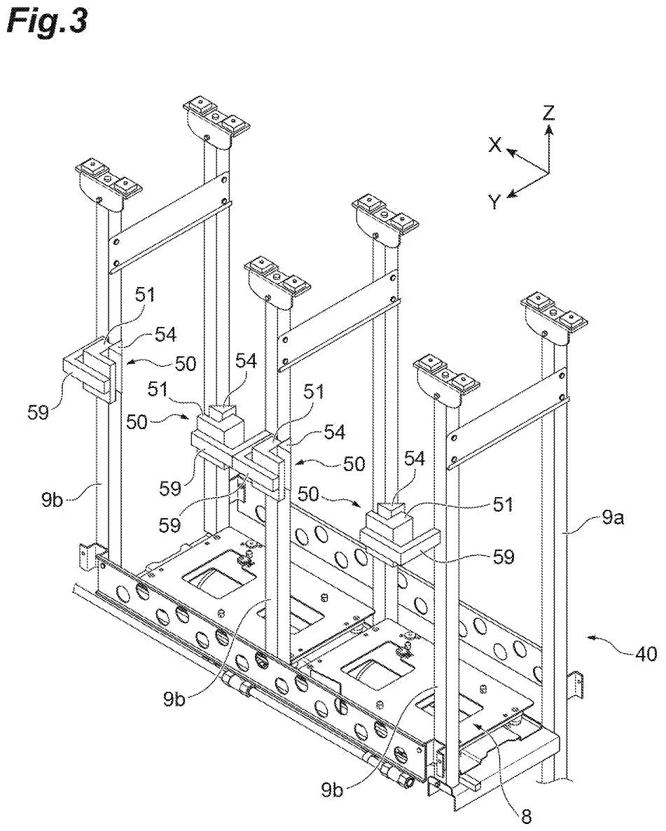

More precisely, a structure to limit an excessive penetration of the lateral move unit 11 in the Y direction is provided to the storage shelf 40 of this example. As illustrated in FIG. 3, the storage shelf 40 includes a plurality of stoppers 50 provided to come into contact with a part of the lateral transfer mechanism 7 when the lateral move unit 11 of the lateral transfer mechanism 7 penetrates (moves) in the Y direction by a predetermined amount or more. In the example illustrated in FIG. 3, two shelf posts 9 are provided on each side of the X direction (four in total) for space for one article 10. Hereafter, a transport vehicle 6 (the transport vehicle 6 on the right side traveling on the first track 4A illustrated in FIG. 2) that intends to transfer the article 10 is referred to as “first transport vehicle 6.” The shelf post 9 includes a shelf post 9a, which is closer to the first transport vehicle 6, and a shelf post 9b, which is farther from the first transport vehicle 6. In the storage shelf 40, a pair (two) of stoppers 50, 50 are attached to a pair of shelf posts 9b with a plurality of brackets 59.

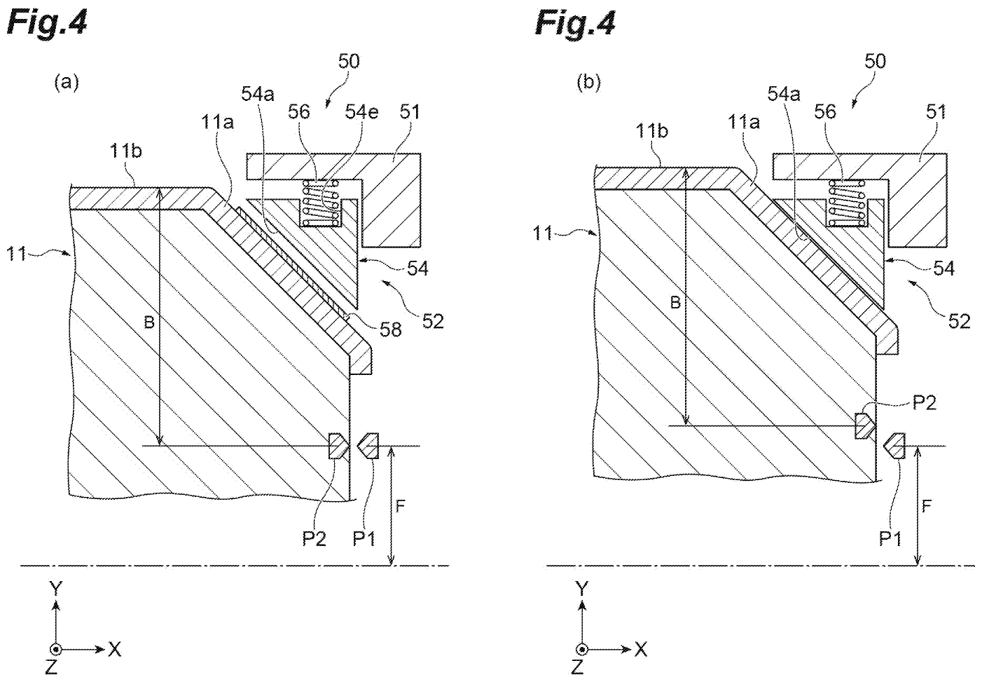

As illustrated in FIGS. 2 and 3, the stoppers 50, 50 are installed, for example, at a height approximately equal to two pieces of corner portions 11a in the upper part of the lateral move unit 11. The lateral move unit 11 is positioned and controlled to advance in the Y direction (transfer direction) by a predetermined advancement amount during normal lateral transfer operation. A contact surface 54a (see FIG. 4(a)) of the stopper 50 is disposed at a position to come into contact with the corner portion 11a (a part of the lateral transfer mechanism 7) when the lateral move unit 11 (see FIG. 6) of the lateral transfer mechanism 7 penetrates in the Y direction by a predetermined amount or more. This “predetermined amount” is set to a value slightly larger than the predetermined advancement amount described above. Therefore, in normal lateral transfer operation, the lateral move unit 11 of the lateral transfer mechanism 7 does not come into contact with the stopper 50. However, if the lateral move unit 11 enters the storage shelf 40 in the transfer direction by a predetermined amount or more due to some abnormalities in the first transport vehicle 6 or other reasons, the corner portion 11a comes into contact with the stopper 50.

As illustrated in FIGS. 1 to 3, the stopper 50 is disposed in an area R that extends in the Y direction beyond an area above the loading portion 8 on which the article 10 is placed, to an opposite side of the first transport vehicle 6, for example. The stopper 50 is installed, for example, in the Y direction, in an area R that extends beyond the shelf post 9b to the opposite side of the first transport vehicle 6. Depending on a size of the storage shelf 40, the stopper 50 may be installed at the same position as the shelf post 9b in the Y direction or in an area that overlaps the shelf post 9b in the Y direction. The stopper 50 is installed in a position where the lateral move unit 11 stops by coming into contact with the stopper 50 before a limit at which the lateral move unit 11 is mechanically operable (stroke limit). The advancement amount by which the lateral move unit 11 comes into contact with the stopper 50 is set to be larger than the above-described predetermined advancement amount and smaller than an operation limit amount (stroke limit) of the lateral move unit 11, based on a regular advancement amount of the lateral move unit 11.

Referring to FIG. 4(a) for a more detailed description of a configuration of the stopper the stopper 50 has a base unit 51 having an L shape fixed to the bracket 59 and an elastic portion 52 attached to a side surface facing the corner portion 11a of the lateral move unit 11 in the base unit 51. The elastic portion 52 includes a contact piece 54 having a triangular prism-shape that is movable in the Y direction with respect to the base unit 51, and a spring 56 that is, for example, a compression coil spring, held in a spring retaining recess 54e of the contact piece 54. A base end of the spring 56 is engaged with the base unit 51, and a tip of the spring 56 is disposed inside of the spring retaining recess 54e and engaged with the contact piece 54. The contact piece 54 is separated from the base unit 51 in the Y direction and is movable in the Y direction within a range of a gap between the base unit 51 and the contact piece 54. The contact piece 54 horizontally faces the first transport vehicle 6 and horizontally faces the corner portion 11a of the lateral move unit 11 configured to advance from the first transport vehicle 6.

The corner portion 11a, for example, has an inclined surface that slopes with respect to the X and Y directions, and the contact surface 54a of the contact piece 54 is inclined similarly as the corner portion 11a is. In other words, the contact surface 54a of the stopper 50 has a shape along a part of the lateral transfer mechanism 7 (the portion coming into contact with the stopper 50). When the corner portion 11a has a rounded shape (curved shape), the contact surface 54a may have a curved shape along the shape of the corner portion 11a.

The elastic portion 52 including the contact piece 54 and the spring 56 exerts a force, when coming into contact with the lateral move unit 11 of the lateral transfer mechanism 7, on the lateral move unit 11 in a direction of decelerating (that is, stopping) the lateral move unit 11.

The corner portion 11a may be provided, for example, at a tip end of the lower member 24c of the lateral transfer unit 24. The corner portion 11a may be provided at a tip end of the θ drive 26 or of the lifting drive unit 28 instead of the lateral transfer unit 24. The corner portion 11a is provided at either end of the lateral move unit 11.

The corner portion 11a is provided with a contact sensor 58 configured to detect contact with the stopper 50, for example. The contact sensor 58, for example, when detecting contact with the stopper 50, outputs a signal. Examples of the contact sensor 58 include, for example, a tape switch or the like. A signal from the contact sensor 58 is sent to the controller, which is not illustrated. When contact with the stopper 50 is detected by the contact sensor 58, control is performed by the controller to stop the lateral transfer mechanism 7, stop traveling of the transport vehicle 6, or generate an alarm to inform the operator. In figures other than FIG. 4(a), illustration of the contact sensor 58 is omitted.

With the storage shelf 40 and the overhead transport vehicle system 1 of this example, when the lateral transfer mechanism 7 of the transport vehicle 6 penetrates in the transfer direction by a predetermined amount or more, the stopper 50 comes into contact with the corner portion 11a of the lateral transfer mechanism 7. This “predetermined amount” is set larger than the penetration amount (advancement amount) in the Y direction that is controlled for positioning in the normal lateral transfer operation. In the normal lateral transfer operation, the lateral transfer mechanism 7 never comes into contact with the stopper 50 (see FIG. 4(a)). In other words, in the normal lateral transfer operation, a transfer position P2 in the lateral move unit 11 of the lateral transfer mechanism 7 coincides with the loading position P1 in the Y direction. The transfer position P2 is illustrated as the center position in the Y direction of the article 10 gripped by the gripping part 31 of the lifting platform 30. In this state, there is a gap between a tip of the corner portion 11a and the contact surface 54a of the stopper 50. However, even if the lateral transfer mechanism 7 penetrates in the Y direction by a predetermined amount or more due to some abnormalities in the transport vehicle 6 or other reasons, the stopper 50 can prevent the lateral transfer mechanism 7 from protruding to the far side in the Y direction (transfer direction). As a result, it is possible to dispose the second track 4B (another track) that can be disposed on the opposite side of the first track 4A, and the transport vehicle 6 and the like closer to each other, thereby increasing the degree of layout flexibility. In the overhead transport vehicle system 1, the second track 4B that can be disposed on the opposite side of the first track 4A, and the transport vehicle 6 or the like have a greater degree of layout flexibility.

The first track 4A and the second track 4B are laid on both sides of the storage shelf Even if the lateral transfer mechanism 7 of the transport vehicle 6 traveling on the first track 4A penetrates in the transfer direction by a predetermined amount or more, the lateral transfer mechanism 7 is prevented from protruding to the far side. Therefore, the lateral transfer mechanism 7 is prevented from coming into contact with the transport vehicle 6 traveling on the second track 4B.

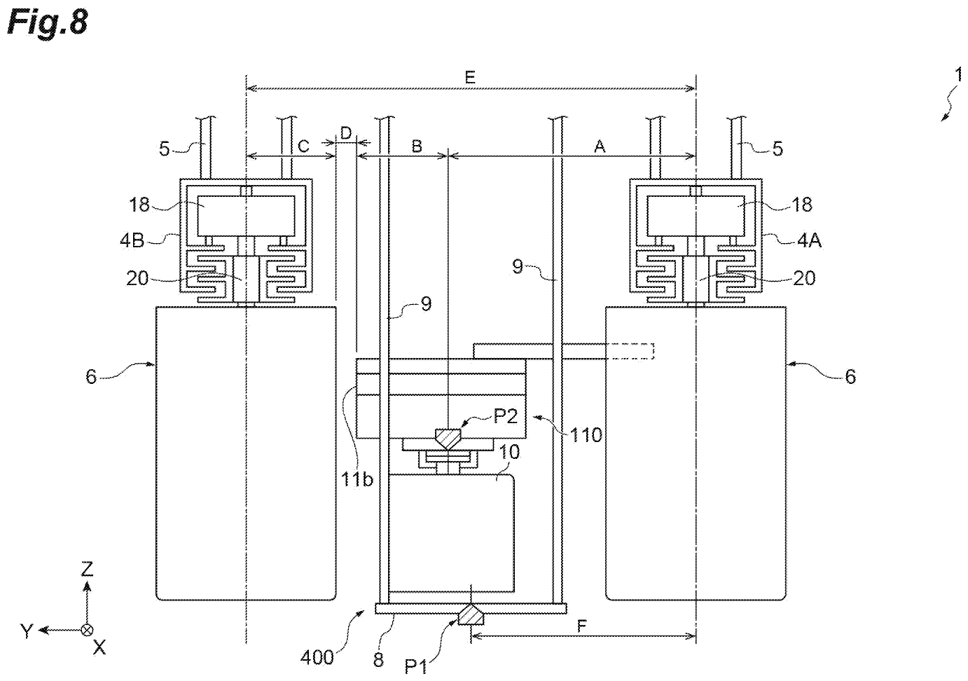

As illustrated in FIG. 8, in the conventional storage shelf 400 not provided with the stoppers 50, sufficient track spacing needs to be provided to prevent such contact. For example, in FIG. 8, A indicates a distance (stroke limit) to the transfer position P2 as an operable maximum position of the lateral transfer mechanism 7, based on the center of the first track 4A. B indicates a dimension from the transfer position P2 of the lateral transfer mechanism 7 to an outline of the transport vehicle 6 (on the opposite side) traveling in an opposite lane. C indicates a dimension from the center of the second track 4B to the outline of the transport vehicle 6 traveling in the opposite lane. D indicates a distance between the outline (tip 11b) of the lateral move unit 11 and the outline of the transport vehicle 6 traveling in the opposite lane. E indicates a distance between the tracks. F indicates a distance from the center of the first track 4A to the loading position P1. Conventionally, sufficient track spacing has been provided such that E, that is, the sum of A, B, C, and D, is greater than F. Therefore, a certain amount of installation area is required, which is a factor that limits a flexible layout.

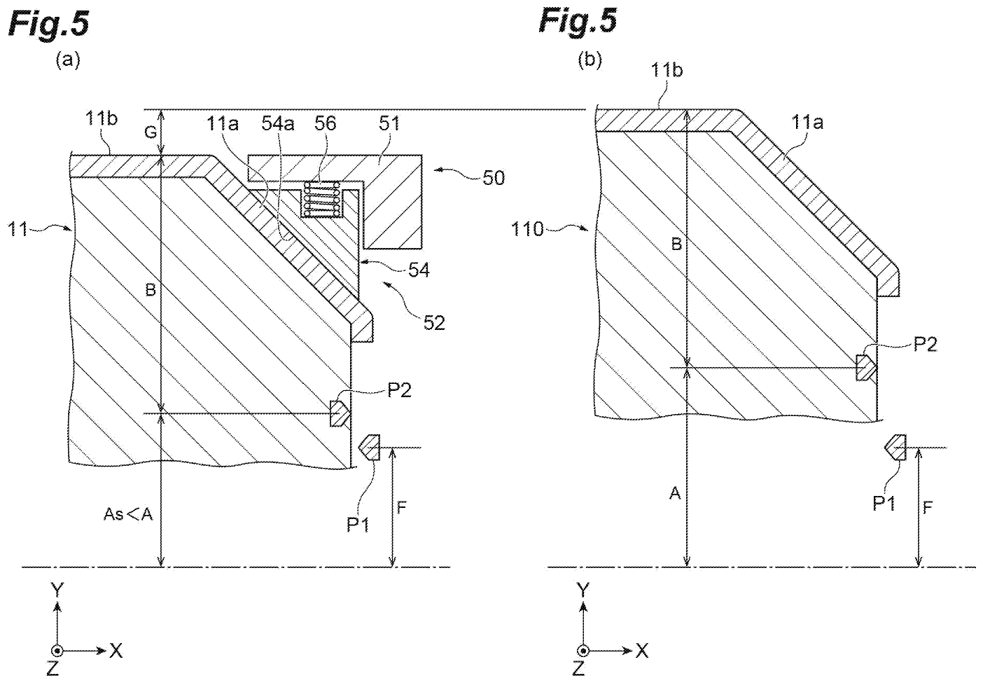

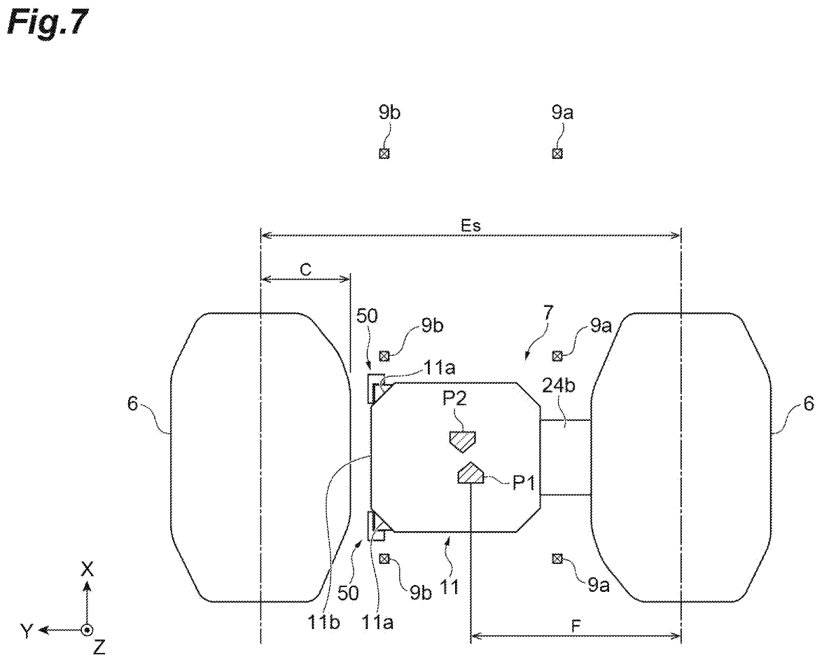

However, in the storage shelf 40 including the stopper 50 of this example, a distance Es between the centers of the first track 4A and the second track 4B can be smaller than track spacing E that has been conventionally required. As illustrated in FIGS. 6 and 7, As is a distance to the transfer position P2 of the lateral transfer mechanism 7, in a state when the lateral move unit 11 is stopped by the stopper 50, based on the center of the first track 4A. Es is the distance between the tracks when the stopper 50 is installed. In the storage shelf 40 of the present disclosure, as illustrated in FIG. 5(a), even if the transport vehicle 6 has the occurrence of some abnormalities and becomes uncontrollable, the lateral move unit 11 comes into contact with the stopper 50 to stop, and thus the distance Es between the tracks can be set to E, that is, the sum of As, B, C, and D. A position of this stop by the stopper 50 is before the limit (stroke limit) until which the lateral move unit 11 is operable, based on the advancement amount of the lateral move unit 11. The base unit 51 (stopper 50) is retracted (positioned on the transport vehicle 6 side) from, for example, the tip 11b of the lateral move unit 11, which is stopped by the stopper 50. Since the distance As is shorter by a difference G than the distance A (see FIG. 5(b)) based on the transfer position P2 in the lateral move unit 110 (excessively protruded) where the stopper 50 is not installed, the distance Es between the tracks can be reduced by that difference G. In recent years, many storage shelves 40 (buffers) have tended to be installed to store the articles 10. Space between the tracks 4, 4 is utilized as an installation place for the storage shelves 40. A smaller space between the tracks 4, 4 allows for a smaller overall factory area (reduced footprint).

The stopper 50 has an elastic portion 52 attached to the side surface facing a part of the lateral transfer mechanism 7. In some instances, although the lateral transfer mechanism 7 comes into contact with the stopper 50, the movement (penetration) of the lateral transfer mechanism 7 does not stop immediately, that is, the lateral transfer mechanism 7 coasts (moves by inertia). Even if the lateral transfer mechanism 7 coasts, the elastic portion 52 of the stopper 50 absorbs the impact while deforming (see FIGS. 4(b) and 5(a)). As a result, it is possible to prevent damage to the stopper 50 and the lateral transfer mechanism 7 (specifically, the corner portion 11a) at the time of contact.

In the overhead transport vehicle system 1, the corner portion 11a of the lateral transfer mechanism 7 of the transport vehicle 6 is provided with the contact sensor 58 configured to detect contact with the stopper 50. The contact sensor 58 can detect contact of the lateral transfer mechanism 7 with the stopper 50. Controls such as stopping the lateral transfer mechanism 7, stopping the transport vehicle 6, and generating an alarm to inform an operator are enabled.

Although an example of our shelves and systems is described, this disclosure is not limited to the above-described example. For example, as described above, the stopper 50 includes the base unit 51, the contact piece 54, and the spring 56 (elastic portion 52), each of which is a separate member, but they may be formed as a single unit. In addition, this disclosure is not limited to when the elastic portion 52 is provided to a part of the stopper 50 as in the above-described example, and a stopper including an elastic body may be provided to the storage shelf. Even in such a situation, it is possible to prevent damage to the stopper and the lateral transfer mechanism 7 at the time of contact of the lateral transfer mechanism 7.

A configuration may be employed in which, for example, instead of elastic deformation by an elastic body, a plastically deformable member may be provided to the stopper or the stopper may be constituted by a plastically deformable member. It is considered to be rare that the lateral transfer mechanism 7 comes into contact with the stopper. Plastic deformation may be used to absorb the impact of the lateral move unit 11, and the stopper (or only the plastically deformable member) may be replaced each time the lateral transfer mechanism 7 comes into contact with the stopper.

Not limited to when the transport vehicle 6 traveling in an opposite lane travels in the opposite direction along the X direction, an overhead transport vehicle system may be provided in which the transport vehicle 6 travels in the same direction along the X direction. In addition, it is not limited to when a pair of tracks 4A, 4B parallel to each other are laid. For example, an overhead transport vehicle system 1 may be provided including one track 4 (the first track 4A illustrated in FIG. 2) and one or more storage shelves 40 installed on the side of the track 4. In other words, the second track 4B may be omitted. Even in such a situation, it is possible to dispose other devices or apparatuses that can be disposed on the opposite side of the first track 4A closer to each other, thereby increasing the layout flexibility. In addition, the storage shelf 40 can also be installed in close proximity to a wall of a factory or the like.

Not limited to when the pair of stoppers 50 are installed, only one of the stoppers 50 may be provided for a single transport vehicle 6 (one loading portion 8). In the above-described example, the stoppers 50 are provided at positions corresponding to the two corner portions 11a of the lateral move unit 11, but the stopper 50 or the stoppers 50 may be provided at a position or positions corresponding to any one or three or more positions other than the corner portions 11a of the lateral move unit 11, and when the lateral transfer mechanism 7 penetrates in the transfer direction by a predetermined amount or more, the stopper 50 or the stoppers 50 may come into contact with one or three or more positions.

The corner portion 11a is not limited to being provided at any of the tip ends of the lateral move unit 11, but may also be provided in a middle portion of the lateral move unit 11 in the Y direction, for example, in a manner of protruding in the X direction. In that example, the stopper may be installed near the area on the loading portion 8 on which the article 10 is placed. The stopper may be installed in an area between the shelf posts 9a, 9b (see FIGS. 2 and 3) in the Y direction. The stopper may be installed at the same position as the shelf post 9a in the Y direction or in an area that overlaps the shelf post 9a in the Y direction, corresponding to the first transport vehicle 6. One or more other parts of the lateral transfer mechanism 7 that are different from the lateral move unit 11 may come into contact with the stopper.

1.-6. (canceled)

7. A storage shelf installed on a side of a track, and to and from which an article is delivered by a lateral transfer mechanism of an overhead transport vehicle traveling in the track in a traveling direction,
the storage shelf comprising: a stopper configured to come into contact with a part of the lateral transfer mechanism having moved by a predetermined amount or more in a lateral direction perpendicular to the traveling direction.

8. The storage shelf as claimed in claim 7, wherein the stopper has an elastic portion attached to a side surface facing a part of the lateral transfer mechanism.

9. The storage shelf according to claim 7, wherein the stopper includes an elastic body.

10. An overhead transport vehicle system comprising:
an overhead transport vehicle traveling along a track; and
a storage shelf installed on a side of the track, to and from which an article is delivered by a lateral transfer mechanism of an overhead transport vehicle traveling in the track in a traveling direction,
wherein the storage shelf includes a stopper configured to come into contact with a part of the lateral transfer mechanism having moved by a predetermined amount or more in a lateral direction perpendicular to the traveling direction.

11. The overhead transport vehicle system according to claim 10, further comprising another track parallel to the track, wherein the storage shelf is installed between the track and the other track.

12. The overhead transport vehicle system according to claim 10, wherein a part of the lateral transfer mechanism of the overhead transport vehicle is provided with a contact sensor configured to detect contact with the stopper.

13. The overhead transport vehicle system according to claim 11, wherein a part of the lateral transfer mechanism of the overhead transport vehicle is provided with a contact sensor configured to detect contact with the stopper.
